(19) United States
(12) Patent Application Publication
(10) Pub. No.: US 2026/0339402 A1
(43) Pub. Date: Oct. 29, 2026

(54) THERMAL MANAGEMENT BASED ON INFERRED FAN OPERATING POINTS

(71) Applicant: Dell Products L.P., Round Rock, TX (US)

(72) Inventors: ABIGAIL MARIE MEZA, Round Rock, TX (US); CARLOS GUILLERMO HENRY, George Town, TX (US); CHRISTIANA ANTONOPOULOU, Edinburgh (GB)

(21) Appl. No.: 19/192,502

(22) Filed: Apr. 29, 2025

(51) Int. Cl. G06F 1/20; H05K 7/20

(52) U.S. Cl. CPC G06F 1/206; H05K 7/20727

(57) ABSTRACT

Methods and systems for thermal management of a data processing system are disclosed. To improve a likelihood of desired computer-implemented services being provided, the systems may thermally manage hardware components of the data processing system using fans. Airflow rates and pressure ratings for the fans while operating in the data processing system may be inferred based on measured power consumption rates and operating rates for each fan. The airflow rates and pressure ratings may be inferred using a function fitted to previously measured power consumption rates and operating rates over a range of airflow rates and pressure ratings for the fans. The inferred airflow rates and pressure ratings may be used to identify and remediate undesired conditions impacting the data processing system.

### FIELD

Embodiments disclosed herein relate generally to thermal management. More particularly, embodiments disclosed herein relate to thermal management for a data processing system using fans.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1A shows a diagram illustrating a data processing system in accordance with an embodiment.

FIG. 1B shows a diagram illustration a flow of gas in a data processing system in accordance with an embodiment.

FIG. 2 shows a data flow diagram in accordance with an embodiment.

FIG. 3 shows a flow diagram illustrating a method in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for thermal management of a data processing system that may be used to provide computer-implemented services. Specifically, the disclosed thermal management method and systems may improve the likelihood of a data processing system providing desired computer-implemented services by improving the thermal management of hardware resources of the data processing system.

To improve the likelihood of the desired computer-implemented services being provided, the systems may include fans that generate airflow to cool various hardware components of the data processing system. For example, each fan of the fans may operate in a manner that may cooperatively cool the various hardware components. While performing its functionality, each fan may operate an operating point (e.g., an airflow rate, a pressure rating, etc.) based on a state of the data processing system.

However, undesired conditions may negatively impact an ability of the fans to thermally manage the data processing system. For example, the undesired conditions may include an undesired airflow pattern, a reduced health state of a fan, unexpected positioning of hardware components that may impede airflow, and/or any other conditions. At least one undesired condition may be identified based on the operating point at which the fans may operate. However, the operating point for the fans may not be accurately measured (e.g., using existing sensors) for the data processing system.

To identify the operating point, an airflow rate and a pressure rating may be inferred for each fan of the data processing system. To do so, a power consumption rate and an operating rate (e.g., rotational speed of blades) for each fan may be measured (e.g., by a thermal manager of the data processing system). The power consumption rate and the operating rate may be used as input to an inference model to infer the corresponding airflow rate and pressure rating for a fan. The inference model may include, for example, a polynomial function obtained based on previously measured power consumption rates and operating rates for fans over a range of pressure ratings and airflow rates.

As such, the airflow rates and pressure ratings for the fans may be used to determine whether an undesired condition is impacting the data processing system. For example, the airflow rates and the pressure ratings may be compared to expected airflow rates and pressure ratings based on topography information for hardware resources of the data processing system. By doing so, a remediation process may be performed to attempt to mitigate an impact of the undesired condition to facilitate continued provisioning of computer-implemented services by the data processing system.

Thus, embodiments disclosed herein may provide a method for thermally managing a data processing system by inferring airflow rates and power ratings of fans used by the data processing system based on power consumption rates and operating rates of the fans. The inferred airflow rates and power ratings of the fans may be used to identify potential undesired conditions impacting the data processing system with respect to thermal management.

In an embodiment, a method for thermally managing a data processing system that provides computer-implemented services is provided. The method may include: (i) for each fan of a plurality of fans of the data processing system: (a) measuring a power consumption rate to obtain power consumption rates of the plurality of fans, and (b) measuring an operating rate to obtain operating rates of the plurality of fans; (ii) for each fan of the plurality of fans: inferring, using a corresponding power consumption rate of the power consumption rates and a corresponding operating rate of the operation rates: (a) an airflow rate to obtain airflow rates for the plurality of fans, and (b) a pressure rating to obtain pressure ratings for the plurality of fans; (iii) making, based on at least a portion of the airflow rates and the pressure ratings, a determination regarding whether an undesired condition is impacting the data processing system; and (iv) in an instance of the determination where the undesired condition is impacting the data processing system: (a) performing a remediation process to attempt to mitigating impacts of the undesired condition to facilitate continued provisioning of the computer-implemented services.

Inferring the airflow rate and the pressure rating may include: (i) using a power consumption rate and an operating rate for a fan of the plurality of fans as input to an inference model to obtain the airflow rate and the pressure rating.

The inference model may include a fitted polynomial function obtained based on previously measured power consumption rates and operating rates over a range of static pressures and airflow rates for at least one fan of the plurality of fans.

Making the determination may include: (i) comparing the portion of the airflow rates and the pressure ratings to topography information for hardware resources of the data processing system.

Making the determination may include: (i) comparing the portion of airflow rates to expected airflow rates over a range of power consumption rates and operating rates for a corresponding portion of fans of the plurality of the fans.

Making the determination may include: (i) comparing the portion of pressure ratings to expected pressure ratings over a range of power consumption rates and operating rates for a corresponding portion of fans of the plurality of the fans.

The undesired condition may include at least one condition from a list of conditions consisting of: (i) an undesired airflow pattern; (ii) a reduced health state of a fan; and (iii) undesired operation relative to positioning of hardware resources of the data processing system.

The airflow rate may be a rate of airflow through a fan of the plurality of fans.

The pressure rating may be a static pressure a fan of the plurality of fans.

The operation rate may include a rotational speed with which a rotating component of a fan of the plurality of fans operates, the rotating component comprising blades of the fan.

In an embodiment, a non-transitory media is provided. The non-transitory media may include instructions that when executed by a processor cause the computer-implemented method to be performed.

In an embodiment, a system is provided. The system may include the non-transitory media and a processor, and may perform the computer-implemented method when the computer instructions are executed by the processor.

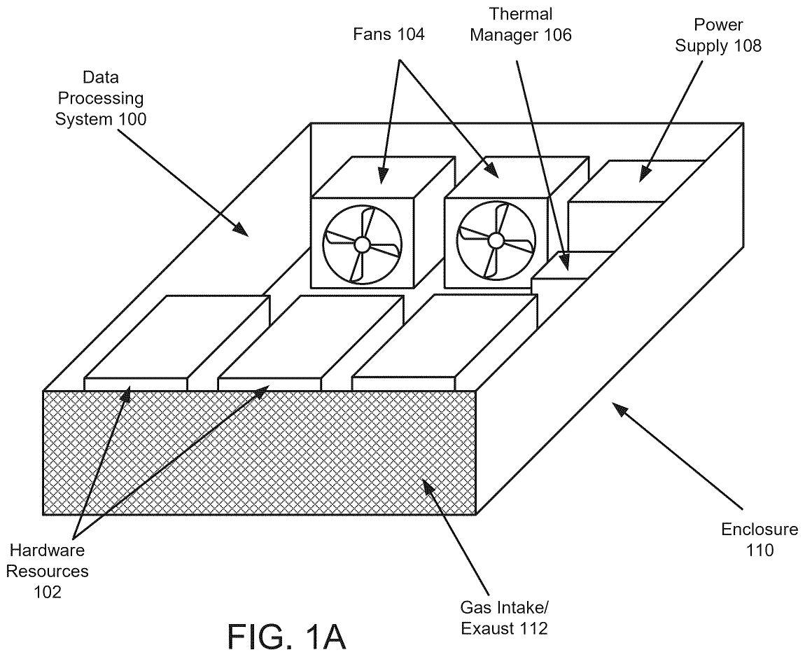

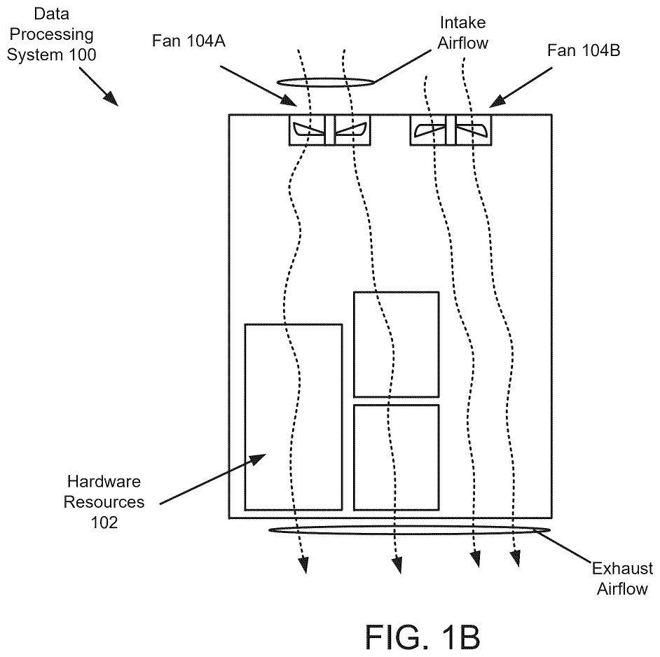

Turning to FIG. 1A, a diagram illustrating a system in accordance with an embodiment is shown. The system shown in FIG. 1A may be used to provide computer-implemented services. The system may include, but is not limited to, data processing system 100 and enclosure 110. Each of these components is discussed below.

Data processing system 100 may provide the computer-implemented services. When doing so, data processing system 100 may consume electrical power from other sources (e.g., via power supply 108 or another device external to the data processing system, either of which may obtain power from a utility or other source). To provide the computer-implemented services, data processing system 100 may include hardware resources 102 and power supply 108.

Hardware resources 102 may include any number of physical devices (e.g., processors, memory modules, storage devices, communications devices, etc.) that provide computing resources (e.g., processor cycles, transitory storage, persistent storage, communications bandwidth, etc.) usable to provide the computer-implemented services. The computing resources may be used to support applications (e.g., computing instructions executing with the computing resources) hosted by data processing system 100. The applications may provide the computer-implemented services. The computer-implemented services may include any type and quantity of computer-implemented services such as, for example, database services, data storage services, electronic communications services, etc. Data processing system 100 may provide other types of computer-implemented services without departing from embodiments disclosed herein.

When operating, hardware resources 102 may consume electrical power to provide the computing resources used to provide the computer-implemented services. The hardware resources may utilize power from power supply 108, and/or other sources. Power supply 108 may include any number of physical devices (e.g., transformers, current/voltage sensors, controllers, etc.) usable to obtain power from other power sources (not shown) and provide conditioned power to hardware resources 102 and/or other components. The power obtained from the other power sources may be any form of power (e.g., alternating current, direct current) but the conditioned power may have specific characteristics (e.g., direct current of a predetermined voltage level) based on the hardware resources 102. For example, hardware resources 102 may not operate as expected when hardware resources 102 are provided with power that is not conditioned power.

Hardware resources 102 may generate heat when providing their functionality. For example, hardware resources 102 may consume power when providing computing resources and generate heat as a byproduct. Generally, hardware resources 102 and/or other components of data processing system 100 may have associated thermal ranges in which the hardware resources 102 are capable of operating (e.g., at high reliability). If the temperatures of various portions of hardware resources 102 fall outside of the thermal ranges, then the corresponding portions of hardware resources 102 may fail to operate (e.g., as intended/expected), may operate with some impairment (e.g., reduced rate, increased error rates in operation, etc.), or may otherwise operate in a manner that may impair (partially or entirely) the ability of data processing system 100 of providing the computer-implemented services.

Data processing system 100 may include one or more fans 104 and thermal manager 106 to thermally manage hardware resources 102. Fans 104 may thermally manage hardware resources 102 by selectively generating flows of gas proximate to hardware resources 102 which may allow heat from hardware resources 102 to be removed. Removing heat from hardware resources 102 may cool them. The rate at which heat is removed from hardware resources 102 may depend on the rate of the flow of gas proximate to hardware resources 102.

In an embodiment, fans 104 include functionality to modulate the rate of gas flows generated by their operation. For example, a fan may include a motor (e.g., electric) and one or more blades. The rate at which the blades move gasses thereby generating a gas flow may be dependent on the rotation rate of the motor. The rate of rotation of the motor may depend on the quantities of voltage and current with which fans 104 are driven. In an embodiment, the fans 104 are driven with a pulse width modulated voltage. The duty cycle (e.g., ratio of on to off time during each cycle of the pulse width modulated voltage) of the pulse width modulated voltage may control the rate at which fans 104 rotate (e.g., within certain limitations, fans 104 may rotate at a predetermined maximum rate with a 100% duty cycle and at reduced rates depending on the duty cycle).

To manage the operation of fans 104, fans 104 may include tachometers to report operating rates (e.g., rotation rates) to other entities (e.g., thermal manager 106). The tachometers (or other types of sensors) may generate an electrical signal corresponding to the operating rates of fans 104. For example, the tachometers generate pulse trains at a rate corresponding to their respective operating rates.

Thermal manager 106 may manage the thermal environment of data processing system 100. To do so, thermal manager 106 may: (i) collect information regarding temperatures of hardware resources 102 (and/or temperatures of other components), (ii) collect information regarding the operating rates and power consumption rates of fans 104, and (iii) use the collected information, at least in part, to set the operating points of fans 104. To collect information regarding the operating points of fans 104, thermal manager 106 may receive signals (e.g., electrical signals carried via a bus, interface, etc.) from the tachometers (or other types of operating rate reporting devices) of fans 104. The received signals may indicate the operating rates of fans 104. Thermal manager 106 may also collect information regarding the power consumption rates of fans 104, for example, by retrieving the information from sensors (or other types of power consumption reporting devices) that may monitor fans 104. To set the operating rates of fans 104, thermal manager 106 may output signals (e.g., electrical signals carried via a bus, interface, etc.) to fans 104. The output signals may indicate operating points for fans 104 (which fans 104 may implement).

However, data processing system 100 may be subject to undesired conditions that may prevent fans 104 from operating at a desired operating point. For example, fans 104 may operate at an actual operating point based on the signals obtained from thermal manager 106, environmental factors, a topography of hardware resources 102, and/or any other conditions. The actual operating point may deviate from the desired operating point that may allow fans 104 to generate airflow and pressure that aligns with requirements of data processing system 100. As such, fans 104 may not thermally manage hardware resources 102 in an effective manner. Furthermore, the actual operating point (e.g., airflow rate, pressure rating, etc.) may not be accurately identified (e.g., by thermal manager 106 using existing sensors) for managing operation of fans 104.

In general, embodiments disclosed herein relate to system, methods, and devices for improving the quality of computer-implemented services provided by a data processing system. To do so, an operating point of fans 104 may be inferred based on power consumption rates and operating rates of fans 104. The inferred operating point may be used to identify an undesired condition impacting data processing system 100 and remediated to facilitate continued provisioning of desired computer-implemented services by data processing system 100.

To infer an actual operating point, an airflow rate and a pressure rating may be inferred for each fan of fans 104. To do so, a power consumption rate and an operating rate (e.g., rotational speed of blades) for each fan may be measured (e.g., by a thermal manager 106). The power consumption rate and the operating rate may be used as input to an inference model to infer the corresponding airflow rate and pressure rating for a fan. The inference model may include, for example, a polynomial function obtained on previously measured power consumption rates and operating rates for fans over a range of pressure ratings and airflow rates. The polynomial function may be obtained, for example, using a fitting function (e.g., least squares, regressions, etc.), curve fitting tools, and/or any other methods.

As such, the airflow rates and pressure ratings for the fans may be used to determine whether an undesired condition is impacting the data processing system. For example, the airflow rates and the pressure ratings may be compared to expected airflow rates and pressure ratings for the fans and/or based on topography information for hardware resources of the data processing system. By doing so, it may be identified that the fans are not thermally managing the data processing system in an effective manner (e.g., unbalanced airflow patterns, reduced health state of at least one fan, etc.)

Once identified, a remediation process may be performed to attempt to mitigate an impact of the undesired condition to facilitate continued provisioning of computer-implemented services by the data processing system. The remediation process may include, for example, modifying operation of at least one fan, facilitating replacement of at least one fan (e.g., via an alert to a user of data processing system 100), facilitating removal of obstructions, and/or any other processes.

Because the operating point information may be used to select how to operate the fan for thermal management purposes, the thermal management of hardware resources 102 may be more likely to meet thermal management needs of hardware resources 102 thereby improving the likelihood of hardware resources 102 being maintained within temperature ranges where the resources operate as expected. Thus, hardware resources 102 may be more likely to provide the computer-implemented services by being more likely to operate as expected due to the improved thermal management of these resources.

Enclosure 110 may include a physical structure for housing data processing system 100. The physical structure may be a form factor compliant structure such as, for example, a rack mount enclosure for a server. The physical structure may be other types of structures for housing data processing systems without departing from embodiments disclosed herein.

Enclosure 110 may include any number of sub-enclosures such as, for example, server chassis sleds, internal blocks, and/or other structures in which various portions of hardware resources 102 are positioned. Fans 104 may be positioned in enclosure 110 to generate predetermined flows of gasses when fans 104 operate such that the gasses, at least in part, flow by hardware resources 102. Enclosure 110 may include one or more of gas intake/exhaust 112 which may allow gasses to traverse through it. For example, a gas intake or exhaust may be implemented with a hole through enclosure 110. The hole may be entirely or partially covered with a grill, mesh, or other structure which may allow gasses to flow through the intake/exhaust while preventing objects of significant size from moving through the intake/exhaust. Fans 104 may be positioned with respect to the intake and/or exhaust on enclosure 110 to facilitate gas flow through (e.g., in an intake and/or out of an exhaust) of enclosure 110. In this manner, cool gases may be brought into enclosure 110 and heated gases may be exhausted from enclosure 110.

While the system of FIG. 1A has been illustrated as including a limited number of specific components, a system may include different numbers, types, and/or quantities of components without departing from the embodiments disclosed herein.

As noted above, flows of gas (e.g., air from an ambient environment or other source) may be used to cool and/or warm various components positioned within data processing system 100. FIG. 1B shows a top view block diagram of data processing system 100 and example flows of gasses (e.g., airflows) in accordance with an embodiment.

Turning to FIG. 1B, a top view block diagram of a data processing system in accordance with an embodiment is shown in FIG. 1B. As discussed above, embodiments disclosed herein may improve the likelihood of a data processing system providing computer-implemented services by improving the thermal management of the components of the data processing system that provide the computer-implemented services.

To thermally manage components of data processing system 100, data processing system may include fan 104A and fan 104B. When fan 104A and fan 104B are operating, air may flow through the interior of data processing system 100. In FIG. 1B, the airflow is illustrated using arrows with dashed tails to indicate direction and flow path. For example, an intake airflow may be drawn into data processing system 100 through fan 104A and fan 104B and exhausted out of data processing system 100 as exhaust airflows. By doing so, thermal exchange between the flow of gas and hardware resources 102 (e.g., temperature sensitive hardware resources and/or other devices not shown in FIG. 1B) may be used to cool the hardware resources 102.

Airflow rates and/or static pressures required to effectively manage the temperature of hardware resources 102 while in a configuration shown in FIG. 1B may be cooperatively generated by intake airflow generated by fan 104A and fan 104B. However, the airflow rates generated by fan 104A and fan 104B may be different based on the configuration (e.g., a topography of hardware resources 102). The airflow rates and pressure ratings for fan 104A and fan 104B may be inferred based on power consumption rates and operating rates for fan 104A and fan 104B.

For example, because hardware resources 102 may be positioned in a manner that may impede airflow generated by fan 104A more than airflow generated by fan 104B, the airflow generated by fan 104B may be indicated by a higher airflow rate and a lower static pressure compared to the airflow generated by fan 104A. Because the airflow rate and static pressures may not be accurately measured (e.g., using existing sensors) for data processing system 100, the airflow generated by fans 104 may not be desired (e.g., efficient) for thermally managing data processing system 100.

Thus, to improve a likelihood that data processing system 100 may be thermally managed, the airflow rates and pressure ratings may be inferred for fan 104A and fan 104B. To do so, power consumption rates and operating rates may be measured using sensors present in data processing system 100 (e.g., tachometers, sensors of power supply units, etc.). For example, a power consumption rate and an operating rate of fan 104B may be used as input to an inference model (e.g., a polynomial function) obtained based on previously measured data (e.g., power consumption rates and operating rates over a range of pressure ratings and airflow rates) for the fan to obtain the inferred airflow rate and pressure rating for fan 104B. The inferred airflow rate and pressure rating may indicate, for example, that an operating rate for fan 104B may be reduced based on the current topography of hardware resources 102.

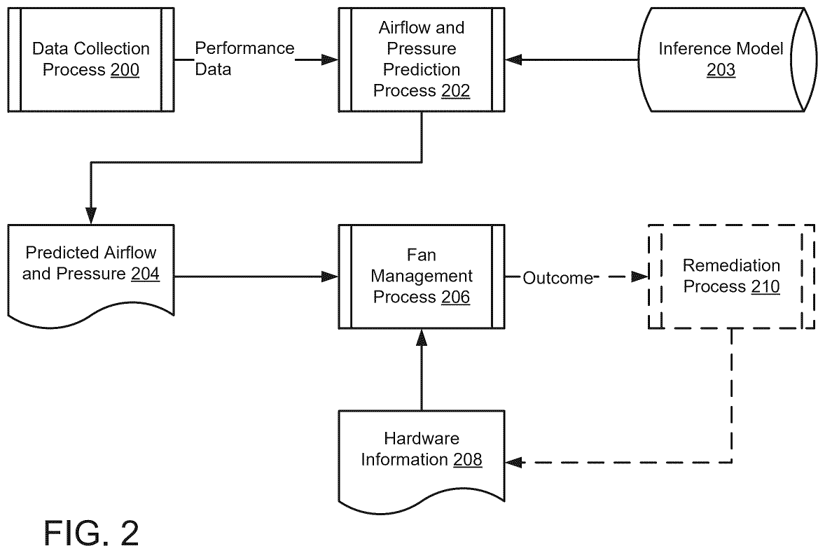

To further clarify embodiments disclosed herein, a data flow diagram in accordance with an embodiment is shown in FIG. 2. In the diagram, flows of data and processing of data are illustrated using different sets of shapes. A first set of shapes (e.g., 204, 208, etc.) is used to represent data structures, a second set of shapes (e.g., 200, 202, etc.) is used to represent processes performed using and/or that generate data, and a third set of shapes (e.g., 203) is used to represent large scale data structures such as databases.

Turning to FIG. 2, a data flow diagram in accordance with an embodiment is shown. The data flow diagram may illustrate data used in and data processing performed in thermally managing a data processing system using fans.

To thermally manage the data processing system, data collection process 200 may be performed. During data collection process 200, performance data for each fan of fans (e.g., 104) may be collected. For example, to collect the performance data, a thermal manager (e.g., 106) may receive information from devices (e.g., a tachometer, sensors, etc.) that may be connected to the fans. The performance data may include, for example, measurements of a power consumption rate and an operating rate (e.g., rotational speed of blades of a fan measured in revolutions per minute (RPM)). The performance data may be collected for each fan of the fans.

To infer an operating point for each fan, airflow and pressure prediction process 202 may be performed. During airflow and pressure prediction process 202, an airflow rate and a pressure rating may be inferred based on the performance data. For example, to infer the airflow rate and the pressure rating for a fan, the performance data may be used as input to inference model 203 to obtain predicted airflow and pressure 204. Inference model 203 may include, for example, a polynomial function fitted to previously collected power consumption and operating rate data for each fan over a range of airflow rates and pressure ratings. For example, test data (e.g., power consumption rates, operating rates, airflow rates, and pressure ratings) may be collected for fans of a second data processing system in a configuration that may be expected of the first data processing system. The test data may be used to obtain an inference model (e.g., a mathematical formula adapted to predict an airflow rate and a pressure rating as a function of a power consumption rate and an operating rate) for each fan and/or fans while operating in a certain configuration (e.g., topography of hardware resources, positioning of fans, etc.).

As such, predicted airflow and pressure 204 may be obtained based on a prediction using the performance data for each fan. Predicted airflow and pressure 204 may include any number and/or type of information regarding an inferred operating point for each fan of the data processing system. For example, an airflow rate of predicted airflow and pressure 204 may indicate a rate of airflow (e.g., volume of air the fan moves in a given amount of time that may be measured in cubic feet of minute) through a fan. A pressure rating of predicted airflow and pressure 204 may indicate a static pressure of the fan (e.g., ability of the fan to move air through resistance).

To identify whether an undesired condition is impacting the data processing system, fan management process 206 may be performed. During fan management process 206, predicted airflow and pressure 204 may be evaluated to obtain an outcome regarding whether the fans are operating in a desired manner to thermally manage the data processing system. To do so, inferred airflow rates and pressure ratings for each fan may be aggregated for the data processing system and/or individually compared to expected airflow rates and pressure ratings for each fan. For example, predicted airflow and pressure 204 may be compared to expected airflow rates and/or pressure ratings for the data processing system as indicated by hardware information 208. The expected airflow rates may include, for example, measured airflows rates over a range of measured power consumption rates and operating rates for a fan. The expected pressure ratings may similarly include, for example, measured pressure ratings over a range of measured power consumption rates and operating rates for a fan. Hardware information 208 may include any number and/or type of information regarding a topography of hardware resources of the data processing system and/or expected airflow rates and/or pressure ratings based on the topography.

In an instance that an undesired condition is identified to be impacting the data processing system (e.g., an outcome obtained during fan management process 206 indicates that an undesired condition is impacting the data processing system relevant to the fans, shown in long dashed lines in FIG. 2), remediation process 210 may be performed to attempt to mitigate an impact of the undesired condition. During remediation process 210, operation of at least a portion of the fans and/or information regarding hardware resources may be updated. For example, a first fan may be instructed to reduce its operating rate (e.g., based on an outcome that indicates that the first fan is operating in a lower impedance environment compared to other fans), facilitating replacement of at least one fan (e.g., via an alert to a user of data processing system), facilitating removal of obstructions, updating hardware information 208 (e.g., based on an outcome that indicates that the topography of the hardware resource may likely be a configuration different from a previous configuration, if previously defined), and/or any other processes.

Thus, using the data flow shown in FIG. 2, airflow rates and pressure ratings for fans of a data processing system may be inferred using measured power consumption rates and operating rates. The inferred airflow rates and pressure ratings may be used to manage operation of the fans in a manner that may facilitate provisioning of desired computer-implemented services by the data processing system (e.g., by modifying airflow through the data processing system to thermally manage hardware resources of the data processing system).

Any of the processes illustrated using the second set of shapes and interactions illustrated using the third set of shapes may be performed, in part or whole, by digital processors (e.g., central processors, processor cores, etc.) that execute corresponding instructions (e.g., computer code/software). Execution of the instructions may cause the digital processors to initiate performance of the processes. Any portions of the processes may be performed by the digital processors and/or other devices. For example, executing the instructions may cause the digital processors to perform actions that directly contribute to performance of the processes, and/or indirectly contribute to performance of the processes by causing (e.g., initiating) other hardware components to perform actions that directly contribute to the performance of the processes.

Any of the processes illustrated using the second set of shapes and interactions illustrated using the third set of shapes may be performed, in part or whole, by special purpose hardware components such as digital signal processors, application specific integrated circuits, programmable gate arrays, graphics processing units, data processing units, and/or other types of hardware components. These special purpose hardware components may include circuitry and/or semiconductor devices adapted to perform the processes. For example, any of the special purpose hardware components may be implemented using complementary metal-oxide semiconductor-based devices (e.g., computer chips).

Any of the processes and interactions may be implemented using any type and number of data structures. The data structures may be implemented using, for example, tables, lists, linked lists, unstructured data, data bases, and/or other types of data structures. Additionally, while described as including particular information, it will be appreciated that any of the data structures may include additional, less, and/or different information from that described above. The informational content of any of the data structures may be divided across any number of data structures, may be integrated with other types of information, and/or may be stored in any location.

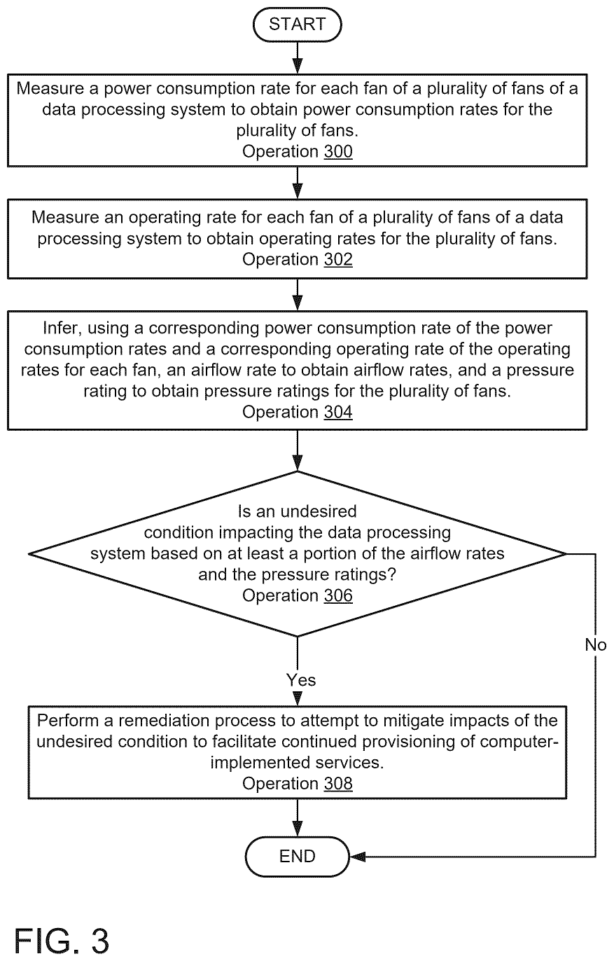

As discussed above, the components of FIG. 1A may perform various methods to manage data processing systems. FIG. 3 illustrates a method that may be performed by the components of the system of FIG. 1A. In the diagrams discussed below and shown in FIG. 3, any of the operations may be repeated, performed in different orders, and/or performed in parallel with or in a partially overlapping in time manner with other operations.

Turning to FIG. 3, a flow diagram illustrating a method of thermally managing a data processing system in accordance with an embodiment is shown. The method may be performed, for example, by any of the components of the system of FIG. 1A, and/or other components not shown therein.

At operation 300, a power consumption rate may be measured for each fan of a plurality of fans of the data processing system. The power consumption rate may be measured by: (i) requesting the power consumption rate for the fan from a power supply unit that supplies power to the fan, (ii) requesting the power consumption rate for the fan from a processor that may obtain data from sensors, (iii) utilizing software adapted to monitor power consumption rates for the fans, and/or via any other methods.

At operation 302, an operating rate may be measured for each fan of the plurality of fans. The operating rate may be measured by: (i) receiving a signal from a tachometer of the fan that may indicate the operating rate, (ii) counting a frequency of pulses/signals received, (iii) utilizing software adapted to monitor operating rates for the fans, and/or via any other methods.

At operation 304, an airflow rate and a pressure rating may be inferred using the power consumption rate and the operating rate for each fan to obtain airflow rates and pressure ratings for the plurality of fans. The airflow rate and the pressure rating may be inferred by obtaining an inference model (e.g., a polynomial function) trained to generate a prediction regarding an airflow rate and the pressure and providing the power consumption rate and the operating rate as input to the polynomial functions to obtain corresponding results. The polynomial function may be obtained by: (i) collecting data by measuring operating rates and power consumption rates for a fan and/or fans in a data processing system over a range of pressure ratings and airflow rates, (ii) preparing the data (e.g., cleaning the data, creating a design matrix, etc.) to obtain a mathematical formula to describe the data, (iii) fitting the data using a curve fitting method (e.g., regression, least squares, etc.) to obtain the polynomial function, (iv) validating the polynomial function using additional test data, and/or performing any other actions.

At operation 306, a determination may be made regarding whether an undesired condition is impacting the data processing system based on at least a portion of the airflow rates and the pressure ratings. The determination may be made by: (i) comparing the inferred airflow rates to expected airflow rates of each fan and/or fans of data processing system (e.g., configuration of hardware resources) over a range of power consumption rates and operating rates to identify a difference between the expected airflow rates and the inferred actual airflow rates, (ii) comparing the inferred pressure ratings to expected pressure ratings of each fan and/or fans of data processing system over a range of power consumption rates and operating rates to identify a difference between the expected pressure ratings and the inferred actual pressure ratings, (iii) identifying that the difference meets criteria (e.g., a threshold) for various undesired conditions, and/or via any other processes.

If it is determined that an undesired condition is impacting the data processing system (e.g., the determination is “Yes” at operation 306), the method may proceed to operation 308. If it is determined that an undesired condition is not impacting the data processing system (e.g., the determination is “No” at operation 306), the method may end following operation 306.

At operation 308, a remediation process may be performed to attempt to mitigate impacts of the undesired condition to facilitate continued provisioning of desired computer-implemented services. The remediation process may be performed by: (i) instructing a fan to reduce its operating rate (e.g., based on an outcome that indicates that the first fan is operating in a lower impedance environment compared to other fans), (ii) instructing a second fan to increase its operating rate (e.g., based on an outcome that indicates that airflow of the second fan does not meet thermal requirements), (iii) providing a notification to a user that a fan is to be replaced, (iv) providing a notification that an unidentified obstruction is impacting airflow of a fan, (v) providing a notification that a hardware configuration may be updated based on airflow patterns of the fans, and/or performing any other actions.

The method may end following operation 308.

Using the method shown in FIG. 3, an undesired condition impacting thermal management of a data processing system using fans may be identified using inferred airflow rates and pressure ratings for the fans and based on measured power consumption rates and operating rates. By doing so, the undesired condition may be remediated to improve a likelihood that the data processing system may be thermally managed to provide desired computer-implemented services.

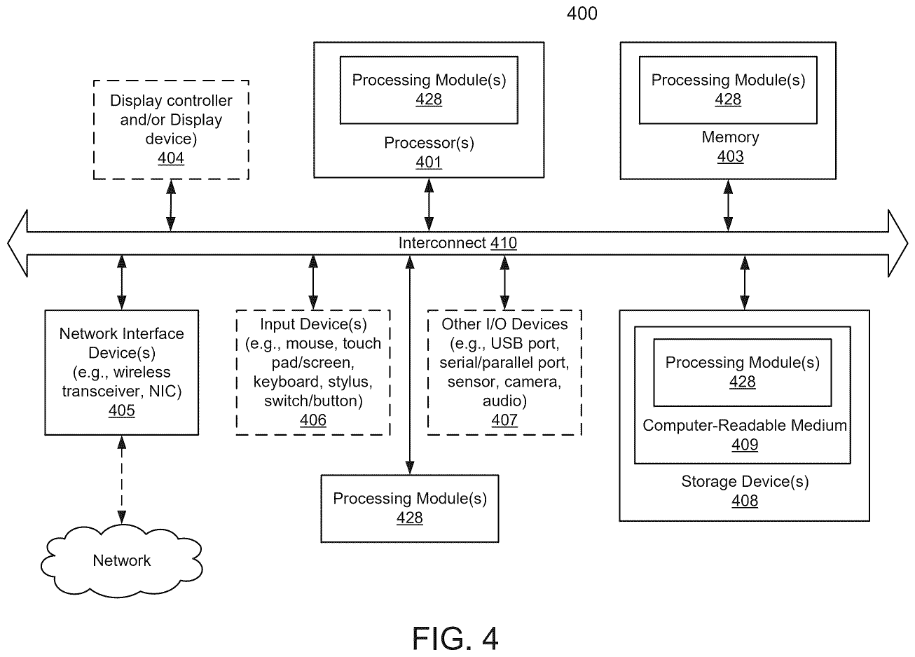

Any of the components illustrated in FIGS. 1A-2 may be implemented with one or more computing devices. Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method of thermally managing a data processing system that provides computer-implemented services, the method comprising:
for each fan of a plurality of fans of the data processing system:
measuring a power consumption rate to obtain power consumption rates of the plurality of fans, and
measuring an operating rate to obtain operating rates of the plurality of fans;
for each fan of the plurality of fans:
inferring, using a corresponding power consumption rate of the power consumption rates and a corresponding operating rate of the operation rates:
an airflow rate to obtain airflow rates for the plurality of fans, and
a pressure rating to obtain pressure ratings for the plurality of fans;
making, based on at least a portion of the airflow rates and the pressure ratings, a determination regarding whether an undesired condition is impacting the data processing system; and
in an instance of the determination where the undesired condition is impacting the data processing system:
performing a remediation process to attempt to mitigate impacts of the undesired condition to facilitate continued provisioning of the computer-implemented services.

2. The method of claim 1, wherein inferring the airflow rate and the pressure rating comprises:
using a power consumption rate and an operating rate for a fan of the plurality of fans as input to an inference model to obtain the airflow rate and the pressure rating.

3. The method of claim 2, wherein the inference model comprises a fitted polynomial function obtained based on previously measured power consumption rates and operating rates over a range of static pressures and airflow rates for at least one fan of the plurality of fans.

4. The method of claim 1, wherein making the determination comprises:
comparing the portion of airflow rates and the pressure ratings to topography information for hardware resources of the data processing system.

5. The method of claim 1, wherein making the determination comprises:
comparing the portion of airflow rates to expected airflow rates over a range of power consumption rates and operating rates for a corresponding portion of fans of the plurality of the fans.

6. The method of claim 1, wherein making the determination comprises:
comparing the portion of the pressure ratings to expected pressure ratings over a range of power consumption rates and operating rates for a corresponding portion of fans of the plurality of the fans.

7. The method of claim 1, wherein the undesired condition comprises at least one condition from a list of conditions consisting of:
an undesired airflow pattern;
an undesired health state of a fan; and
undesired operation relative to positioning of hardware resources of the data processing system.

8. The method of claim 1, wherein the airflow rate is a rate of airflow through a fan of the plurality of fans.

9. The method of claim 1, wherein the pressure rating is a static pressure of a fan of the plurality of fans.

10. The method of claim 1, wherein the operating rate comprises a rotational speed with which a rotating component of a fan of the plurality of fans operates, the rotating component comprising blades of the fan.

11. A non-transitory machine-readable medium having instructions stored therein, which when executed by a processor, cause the processor to perform operations for thermally managing a data processing system that provides computer-implemented services, the operations comprising:
for each fan of a plurality of fans of the data processing system:
measuring a power consumption rate to obtain power consumption rates of the plurality of fans, and
measuring an operating rate to obtain operating rates of the plurality of fans;
for each fan of the plurality of fans:
inferring, using a corresponding power consumption rate of the power consumption rates and a corresponding operating rate of the operation rates:
an airflow rate to obtain airflow rates for the plurality of fans, and
a pressure rating to obtain pressure ratings for the plurality of fans;
making, based on at least a portion of the airflow rates and the pressure ratings, a determination regarding whether an undesired condition is impacting the data processing system; and
in an instance of the determination where the undesired condition is impacting the data processing system:
performing a remediation process to attempt to mitigate impacts of the undesired condition to facilitate continued provisioning of the computer implemented services.

12. The non-transitory machine-readable medium of claim 11, wherein inferring the airflow rate and the pressure rating comprises:
using a power consumption rate and an operating rate for a fan of the plurality of fans as input to an inference model to obtain the airflow rate and the pressure rating.

13. The non-transitory machine-readable medium of claim 12, wherein the inference model comprises a fitted polynomial function obtained based on previously measured power consumption rates and operating rates over a range of static pressures and airflow rates for at least one fan of the plurality of fans.

14. The non-transitory machine-readable medium of claim 11, wherein making the determination comprises:
comparing the portion of airflow rates and the pressure ratings to topography information for hardware resources of the data processing system.

15. The non-transitory machine-readable medium of claim 12, wherein making the determination comprises:
comparing the portion of the airflow rates to expected airflow rates over a range of power consumption rates and operating rates for a corresponding portion of fans of the plurality of the fans.

16. A system, comprising:
a processor; and
a memory coupled to the processor to store instructions, which when executed by the processor, cause the processor to perform operations for thermally managing a data processing system that provides computer-implemented services, the operations comprising:
for each fan of a plurality of fans of the data processing system:
measuring a power consumption rate to obtain power consumption rates of the plurality of fans, and
measuring an operating rate to obtain operating rates of the plurality of fans;
for each fan of the plurality of fans:
inferring, using a corresponding power consumption rate of the power consumption rates and a corresponding operating rate of the operation rates:
an airflow rate to obtain airflow rates for the plurality of fans, and
a pressure rating to obtain pressure ratings for the plurality of fans;
making, based on at least a portion of the airflow rates and the pressure ratings, a determination regarding whether an undesired condition is impacting the data processing system; and
in an instance of the determination where the undesired condition is impacting the data processing system:
performing a remediation process to attempt to mitigate impacts of the undesired condition to facilitate continued provisioning of the computer implemented services.

17. The system of claim 16, wherein inferring the airflow rate and the pressure rating comprises:
using a power consumption rate and an operating rate for a fan of the plurality of fans as input to an inference model to obtain the airflow rate and the pressure rating.

18. The system of claim 17, wherein the inference model comprises a fitted polynomial function obtained based on previously measured power consumption rates and operating rates over a range of static pressures and airflow rates for at least one fan of the plurality of fans.

19. The system of claim 18, wherein making the determination comprises:
comparing the portion of the airflow rates and the pressure ratings to topology information for hardware resources of the data processing system.

20. The system of claim 18, wherein making the determination comprises:
comparing the portion of the airflow rates to expected airflow rates over a range of power consumption rates and operating rates for a corresponding portion of fans of the plurality of the fans.
